(19) United States
(12) Patent Application Publication
(10) Pub. No.: US 2025/0105788 A1
(43) Pub. Date: Mar. 27, 2025

(54) DISTRIBUTED DOUBLE BALANCED MIXER

(71) Applicant: Nippon Telegraph and Telephone Corporation, Tokyo (JP)

(72) Inventors: Teruo Jo, Tokyo (JP); Munehiko Nagatani, Tokyo (JP); Tsutomu Takeya, Tokyo (JP); Hiroyuki Takahashi, Tokyo (JP); Hitoshi Wakita, Tokyo (JP)

(21) Appl. No.: 18/710,771

(22) PCT Filed: Nov. 18, 2021
(86) PCT No.: PCT/JP2021/042392

§ 371 Date: Dec. 11, 2024

(51) Int. Cl. H03D 7/14

(52) U.S. Cl. CPC H03D 7/1458; H03D 7/1433

(57) ABSTRACT

Each unit cell (4a-1 to 4a-N) of the distributed double balanced mixer outputs a signal (R++) obtained by multiplexing the LO signal (LO+) on the positive phase side and the IF signal (IF+) on the positive phase side, a signal (RF−−) obtained by multiplexing the LO signal (LO−) on the negative phase side and the IF signal (IF−) on the negative phase side, a signal (RF−+) obtained by multiplexing the LO signal (LO−) on the negative phase side and the IF signal (IF+) on the positive phase side, and a signal (RF+−) obtained by multiplexing LO signal (LO+) on the positive phase side and IF signal (IF−) on the negative phase side, to transmission lines (CPW20pp, CPW20nn, CPW20np, CPW20pn), without synthesizing the signals.

### TECHNICAL FIELD

The present invention relates to a distributed double balanced mixer using a Gilbert cell.

### BACKGROUND ART

In the field of optical communication, a mixer for performing frequency conversion of a signal is a very important component to expand a band of a digital-to-analog converter (DAC) and an analog-to-digital converter (ADC) (NPL 1). Among mixers, a double balanced mixer (DBM) using a Gilbert cell is used as one having a rejection function of an intermediate frequency (IF) signal and a local oscillator (LO) signal and having a high conversion gain (NPL 2).

In recent years, a mixer having a wider band has been required with the acceleration of optical communication and radio communication. As a technique for widening the bandwidth of a mixer, a distributed double balanced mixer as shown in FIG. 11 is proposed (NPL 1).

The distributed double balanced mixer includes transmission lines CPW10p and CPW10n for IF signal input whose input ends are connected to IF signal input ends 1p and 1n, transmission lines CPW20p and CPW20n for RF signal output whose terminals are connected to radio frequency (RF) signal output terminals 2p and 2n, transmission lines CPW30p and CPW30n for LO signal input whose input ends are connected to LO signal input ends 3p and 3n, input end resistances R1p and R1n for connecting the terminals of the transmission lines CPW10p and CPW10n to the ground, output terminal resistors R2p and R2n for connecting input ends of the transmission lines CPW20p and CPW20n to the ground, terminal resistors R3p and R3n for connecting terminals of the transmission lines CPW30p and CPW30n to the ground, and a plurality of unit cells 4-1 to 4-N(N is an integer of 2 or more) which are disposed along the transmission lines CPW10p, CPW10n, CPW20p, CPW20n, CPW30p, and CPW30n, whose IF input ends are connected to the transmission lines CPW10p and CPW10n, LO input ends are connected to the transmission lines CPW30p and CPW30n, and RF output terminals are connected to the transmission lines CPW20p and CPW20n.

Each of the unit cells 4-1 to 4-N is made up of a Gilbert cell. As shown in FIG. 12, the Gilbert cell is made up of transistors Q1 to Q6 and a constant current source IS.

In the configuration shown in FIGS. 11 and 12, by performing impedance matching in a with the parasitic capacitance of the transistors Q1 to Q6 incorporated into the input and output transmission lines CPW10p, CPW10n, CPW20p, CPW20n, CPW30p, and CPW30n, and by matching the propagation constants of the transmission lines CPW10p, CPW10n, CPW20p, CPW20n, CPW30p, and CPW30n, the frequency conversion of a wide band signal is enabled. Hereinafter, the transmission line to which the parasitic capacitance of the transistor is added is referred to as a pseudo transmission line to distinguish it from a normal transmission line.

The band of the distributed mixer is generally determined by a cut-off frequency of the pseudo transmission line. The smaller the capacitance added to the transmission line per unit length is, the higher the cut-off frequency is.

However, in the distributed double balanced mixer using a Gilbert cell for unit cells 4-1 to 4-N, since parasitic capacitance of two transistors was added to the transmission lines CPW20p and CPW20n on the output side, there was a problem that the cut-off frequency was low and the band was narrow. For example, in the configuration shown in FIGS. 11 and 12, the parasitic capacitance of the transistors Q1 and Q3 is added to the transmission line CPW20p, and the parasitic capacitance of the transistor Q2 and Q4 is added to the transmission line CPW20n.

### CITATION LIST

### Non Patent Literature

[NPL 1] Teruo Jyo, et al., “A DC to 194-GHz Distributed Mixer in 250-nm InP DHBT Technology,” 2020 IEEE/MTT-S International Microwave Symposium (IMS), IEEE, 2020
[NPL 2] Chung-Ru Wu, Hsieh-Hung Hsieh, and Liang-Hung Lu, “An ultra-wideband distributed active mixer MMIC in 0.18-μm CMOS technology,” IEEE transactions on microwave theory and techniques, Vol. 55, No. 4, pp. 625-632, 2007

### SUMMARY OF INVENTION

### Technical Problem

The present invention is made to solve the aforementioned problem, and an object of the present invention is to provide a distributed double balanced mixer with a wider band than before.

### Solution to Problem

A distributed double balanced mixer of the present invention includes: a first transmission line configured to receive an IF signal of a positive phase side at an input end; a second transmission line configured to receive the IF signal of a negative phase side at an input end; a third transmission line configured to receive an LO signal of the positive phase side at an input end; a fourth transmission line configured to receive an LO signal of the negative phase side at an input end; a fifth transmission line configured to output a signal obtained by multiplexing the LO signal of the positive phase side and the IF signal of the positive phase side; a sixth transmission line configured to output a signal obtained by multiplexing the LO signal of the negative phase side and the IF signal of the negative phase side; a seventh transmission line configured to output a signal obtained by multiplexing the LO signal of the negative phase side and the IF signal of the positive phase side; an eighth transmission line configured to output a signal obtained by multiplexing the LO signal of the positive phase side and the IF signal of the negative phase side; first and second terminal resistors connected to terminals of the first and second transmission lines; third and fourth terminal resistors connected to terminals of the third and fourth transmission lines; fifth to eighth terminal resistors connected to input ends of the transmission lines of the fifth to eighth transmission lines, respectively; and a plurality of unit cells which are disposed along the first to eighth transmission lines, and in which an IF input terminal is connected to the first and second transmission lines, an LO input terminal is connected to the third and fourth transmission lines, and RF output terminals are connected to the fifth to eighth transmission lines. The unit cells include a first transistor having a base terminal connected to the third transmission line and a collector terminal connected to the fifth transmission line, a second transistor having a base terminal connected to the fourth transmission line and a collector terminal connected to the seventh transmission line, a third transistor having a base terminal connected to the fourth transmission line and a collector terminal connected to the sixth transmission line, a fourth transistor having a base terminal connected to the third transmission line and a collector terminal connected to the eighth transmission line, a fifth transistor having a base terminal connected to the first transmission line and a collector terminal connected to the emitter terminals of the first and second transistors, a sixth transistor having a base terminal connected to the second transmission line and a collector terminal connected to the emitter terminals of the third and fourth transistors, and a constant current source having one end connected to the emitter terminals of the fifth and sixth transistors and the other end connected to the ground.

One configuration example of the distributed double balanced mixer of the present invention is characterized by further including a first multiplexer configured to multiplex an output signal of the fifth transmission line and an output signal of the sixth transmission line to output an RF signal of the positive phase side; and a second multiplexer configured to multiplex an output signal of the seventh transmission line and an output signal of the eighth transmission line to output an RF signal of the negative phase side.

In addition, one configuration example of the distributed double balanced mixer of the present invention is characterized in that the RF signal of the positive phase side is output from a connection point between the terminal of the fifth transmission line and the terminal of the sixth transmission line, and the RF signal of the negative phase side is output from a connection point between the terminal of the seventh transmission line and the terminal of the eighth transmission line.

In one configuration example of the distributed double balanced mixer of the present invention, the fifth to eighth transmission lines have a characteristic impedance of 100Ω.

Further, in one configuration example of the distributed double balanced mixer of the present invention, the first multiplexer is configured by a first passive multiplexer which includes a first resistor of 16.7Ω having one end connected to the terminal of the fifth transmission line, a second resistor of 16.7Ω having one end connected to the terminal of the sixth transmission line, and a third resistor of 16.7Ω which has one end connected to the other ends of the first and second resistors, and is configured to output the RF signal of the positive phase side from the other end, and the second multiplexer is configured by a first passive multiplexer which includes a fourth resistor of 16.7Ω having one end connected to the terminal of the seventh transmission line, a fifth resistor of 16.7Ω having one end connected to the terminal of the eighth transmission line, and a sixth resistor of 16.7Ω which has one end connected to the other ends of the fourth and fifth resistors, and is configured to output an RF signal on the negative phase side from the other end.

In one configuration example of the distributed double balanced mixer of the present invention, the first multiplexer includes a first distributed amplifier which receives an output signal of the fifth transmission line as an input, a second distributed amplifier which receives an output signal of the sixth transmission line as an input, and a first passive multiplexer configured to multiplex an output signal of the first distributed amplifier and an output signal of the second distributed amplifier, and the second multiplexer includes a third distributed amplifier which receives an output signal of the seventh transmission line as an input, a fourth distributed amplifier which receives an output signal of the eighth transmission line as an input, and a second passive multiplexer configured to multiplex the output signal of the third distributed amplifier and the output signal of the fourth distributed amplifier.

In one configuration example of the distributed double balanced mixer of the present invention, the first distributed amplifier includes a ninth transmission line configured receive an output signal of the fifth transmission line at an input end, a tenth transmission line configured to output a signal from the terminal, a ninth terminal resistor having one end connected to the terminal of the ninth transmission line, a tenth terminal resistor having one end connected to the input end of the tenth transmission line, and a plurality of first unit amplifiers which are disposed along the ninth transmission line and the tenth transmission line, and in which an input terminal is connected to the ninth transmission line, and an output terminal is connected to the tenth transmission line. The second distributed amplifier includes an eleventh transmission line configured such that an output signal of the sixth transmission line is input to an input end, a twelfth transmission line configured to output a signal from the terminal, an eleventh terminal resistor having one end connected to the terminal of the eleventh transmission line, a twelfth terminal resistor having one end connected to the input end of the twelfth transmission line, and a plurality of second unit amplifiers which are disposed along the eleventh transmission line and the twelfth transmission line, and in which an input terminal is connected to the eleventh transmission line, and an output terminal is connected to the twelfth transmission line. The third distributed amplifier includes a thirteenth transmission line configured such that an output signal of the seventh transmission line is input to an input end, a fourteenth transmission line configured to output a signal from the terminal, a thirteenth terminal resistor having one end connected to the terminal of the thirteenth transmission line, a fourteenth terminal resistor having one end connected to the input end of the fourteenth transmission line, and a plurality of third unit amplifiers which are disposed along the thirteenth transmission line and the fourteenth transmission line, and in which an input terminal is connected to the thirteenth transmission line, and an output terminal is connected to the fourteenth transmission line. The fourth distributed amplifier includes a fifteenth transmission line configured such that an output signal of the eighth transmission line is input to an input end, a sixteenth transmission line configured to output a signal from the terminal, a fifteenth terminal resistor having one end connected to the terminal of the fifteenth transmission line, a sixteenth terminal resistor having one end connected to the input end of the sixteenth transmission line, and a plurality of fourth unit amplifiers which are disposed along the fifteenth transmission line and the sixteenth transmission line, and in which an input terminal is connected to the fifteenth transmission line, and an output terminal is connected to the sixteenth transmission line. The characteristic impedances of the fifth to eighth transmission lines and the fifth to eighth terminal resistors are higher than 50Ω, and the characteristic impedances of the ninth, eleventh, thirteenth, and fifteenth transmission lines, and the ninth, eleventh, thirteenth and fifteenth terminal resistors are higher than 50Ω.

One configuration example of the distributed double balanced mixer of the present invention further includes a multiplexer configured to multiplex an output signal of the fifth transmission line and an output signal of the sixth transmission line to output an RF signal, in which the seventh transmission line, the fifth transmission line, the sixth transmission line, and the eighth transmission line are disposed on a plane in that order.

### Advantageous Effects of Invention

According to the present invention, each unit cell outputs the fifth to eighth transmission lines as they are without combining the four output signals, thereby realizing a distributed double balanced mixer having a wider band than before.

### BRIEF DESCRIPTION OF DRAWINGS

FIG. 1 is a circuit diagram showing a configuration of a distributed double balanced mixer according to first example of the present invention.

FIG. 2 is a circuit diagram showing a configuration of a unit cell of the distributed double balanced mixer according to the first example of the present invention.

FIG. 3 is a diagram showing simulation results of conversion gain of the distributed double balanced mixer of the related art and according to first example of the present invention.

FIG. 4 is a circuit diagram showing a configuration of a distributed double balanced mixer according to Second example of the present invention.

FIG. 5 is a circuit diagram showing a configuration of a multiplexer according to Third example of the present invention.

FIG. 6 is a circuit diagram showing the configuration of a multiplexer according to Fourth example of the present invention.

FIG. 7 is a circuit diagram showing the configuration of the multiplexer according to the Fourth example of the present invention.

FIG. 8 is a circuit diagram showing the configuration of a unit cell of a distributed amplifier according to Fourth example of the present invention.

FIG. 9 is a circuit diagram showing a configuration of a distributed double balanced mixer according to Fifth example of the present invention.

FIG. 10 is a circuit diagram showing the configuration of a unit cell of the distributed double balanced mixer according to the Fifth example of the present invention.

FIG. 11 is a circuit diagram showing a configuration of a distributed double balanced mixer of the related art.

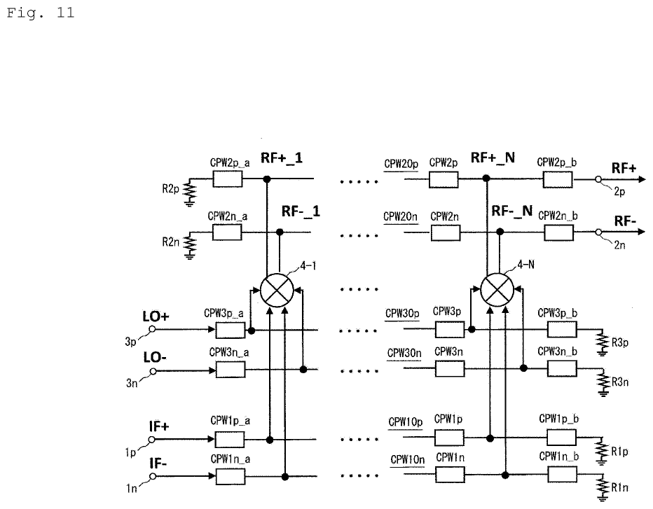

FIG. 12 is a circuit diagram showing a configuration of a unit cell of the distributed double balanced mixer of the related art.

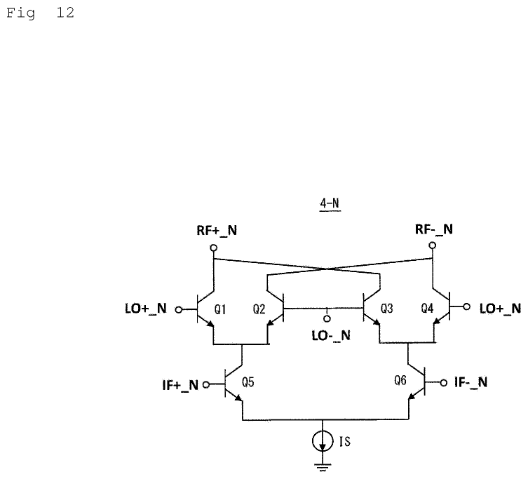

### DESCRIPTION OF EMBODIMENTS

### First Example

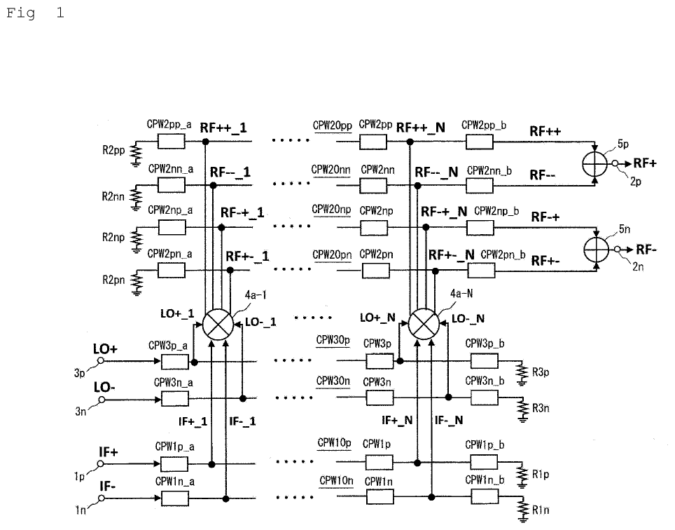

Referring to the drawings, a description will be given of examples of the present invention. FIG. 1 is a circuit diagram showing a configuration of a distributed double balanced mixer according to first example of the present invention. The distributed double balanced mixer of this example includes transmission lines CPW10p and CPW10n for IF signal input (first and second transmission lines) whose input ends are connected to IF signal input ends 1p and In, transmission lines CPW20pp, CPW20nn, CPW20np, and CPW20pn for RF signal output (fifth to eight transmission lines), transmission lines CPW30p and CPW30n for LO signal input (third and fourth transmission lines) whose input ends are connected to LO signal input ends 3p and 3n, input end resistances R1p and R1n for connecting the terminals of the transmission lines CPW10p and CPW10n to the ground, output terminal resistors R2pp, R2nn, R2np, and R2pn for connecting input ends of the transmission lines CPW20pp, CPW20nn, CPW20np, and CPW20pn to the ground, terminal resistors R3p and R1n for connecting terminals of the transmission lines CPW30p and CPW30n to the ground, a plurality of unit cells 4a-1 to 4a-N (N is an integer of 2 or more) which are disposed along the transmission lines CPW10p, CPW10n, CPW20pp, CPW20nn, CPW20np, CPW20pn, CPW30p, and CPW30n, whose IF input ends are connected to the transmission lines CPW10p and CPW10n, LO input ends are connected to the transmission lines CPW30p and CPW30n, and RF output terminals 2p are connected to the transmission lines CPW20pp, CPW20nn, CPW20np, and CPW20pn, a multiplexer 5p which multiplexes the output signal of the transmission line CPW20pp and the output signal of the transmission line CPW20nn with equal amplitude and equal phase to output them to the RF signal output terminal 2p, and a multiplexer 5n which multiplexes the output signal of the transmission line CPW20np and the output signal of the transmission line CPW20pn with equal amplitude and equal phase to output them to the RF signal output terminal 2n.

IF+ of FIG. 1 represents an IF signal on a positive phase side, IF− represents an IF signal on a negative phase side, LO+ represents an LO signal on the positive phase side, LO-represents an LO signal on the negative phase side, RF++ represents a signal obtained by multiplexing the LO signal on the positive phase side and the IF signal on the positive phase side, RF−− is a signal obtained by multiplexing the LO signal on the negative phase side and the IF signal on the negative phase side, RF−+ is a signal obtained by multiplexing the LO signal on the negative phase side and the IF signal on the positive phase side, RF+− is a signal obtained by multiplexing the LO signal on the positive phase side and the IF signal on the negative phase side, RF+ is a RF signal on the positive phase side, and RF− is a RF signal on the negative phase side.

The transmission line CPW10p has a configuration in which a plurality of transmission lines CPW1p_a, CPW1p, and CPW1p_b are connected in series. The transmission line CPW1p between the unit cells and the transmission line CPW1p_a on the input side have different characteristic impedances. The reason is that, in the case of the transmission line CPW1p_a, it is necessary to absorb the influence of the parasitic capacitance of the circuit of the preceding stage by the transmission line CPW1p_a. Similarly, the transmission lines CPW1p and CPW1p_b have different characteristic impedances. The reason is that, in the case of the transmission line CPW1p_b, it is necessary to absorb the influence of the parasitic capacitance of the input terminal resistor R1p by the transmission line CPW1p_b.

Similarly to the transmission line CPW10p, the transmission line CPW10n has a configuration in which a plurality of transmission lines CPW1n_a, CPW1n, and CPW1n_b are connected in series.

The transmission line CPW20pp has a configuration in which a plurality of transmission lines CPW2pp_a, CPW2pp, and CPW2pp_b are connected in series. The transmission line CPW2pp between the unit cells and the transmission line CPW2pp_a on the input side have different characteristic impedances. The reason is that, in the case of the transmission line CPW2pp_a, it is necessary to absorb the influence of the parasitic capacitance of the output terminal resistor R2pp by the transmission line CPW2pp_a. Similarly, the transmission lines CPW2pp and CPW2pp_b have different characteristic impedances. The reason is that, in the case of the transmission line CPW2pp_b, it is necessary to absorb the influence of the parasitic capacitance of the circuit at the subsequent stage by the transmission line CPW2pp_b.

Similarly to the transmission line CPW20pp, the transmission line CPW20pn has a configuration in which a plurality of transmission lines CPW2pn_a, CPW2pn, and CPW2pn_b are connected in series. The transmission line CPW20np has a configuration in which a plurality of transmission lines CPW2np_a, CPW2np, and CPW2np_b are connected in series. The transmission line CPW20nn has a configuration in which a plurality of transmission lines CPW2nn_a, CPW2nn, CPW2nn_b are connected in series.

The transmission line CPW30p has a configuration in which a plurality of transmission lines CPW3p_a, CPW3p, and CPW3p_b are connected in series. The transmission line CPW3p between the unit cells and the transmission line CPW3p_a on the input side have different characteristic impedances. The reason is that, in the case of the transmission line CPW3p_a, it is necessary to absorb the influence of the parasitic capacitance of the circuit of the preceding stage by the transmission line CPW3p_a. Similarly, the transmission lines CPW3p and CPW3p_b have different characteristic impedances. The reason is that in the case of the transmission line CPW3p_b, it is necessary to absorb the influence of the parasitic capacitance of the terminal resistor R3p by the transmission line CPW3p_B.

Similarly to the transmission line CPW30p, the transmission line CPW30n has a configuration in which a plurality of transmission lines CPW3n_a, CPW3n, and CPW3n_b are connected in series.

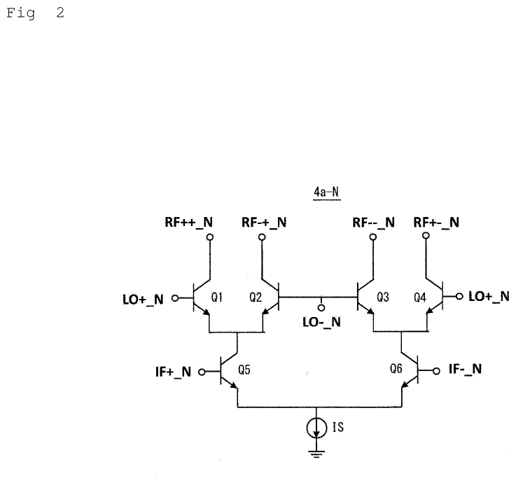

As shown in FIG. 2, each unit cell 4a-N includes an NPN bipolar transistor Q1 whose base terminal is connected to a transmission line CPW30p and collector terminal is connected to a transmission line CPW20pp, an NPN bipolar transistor Q2 whose base terminal is connected to transmission line CPW30n and collector terminal is connected to transmission line CPW20np, an NPN bipolar transistor Q3 whose base terminal is connected to a transmission line CPW30n and collector terminal is connected to a transmission line CPW20nn, an NPN bipolar transistor Q4 whose base terminal is connected to a transmission line CPW30p and collector terminal is connected to a transmission line CPW20pn, an NPN bipolar transistor Q5 whose base terminal is connected to a transmission line CPW10p and collector terminal is connected to emitter terminals of transistors Q1 and Q2, an NPN bipolar transistor Q6 whose base terminal is connected to the transmission line CPW10n and collector terminal is connected to emitter terminals of transistors Q3 and Q4, and a constant current source IS which has one end connected to the emitter terminals of the transistors Q5 and Q6 and the other end is connected to ground, and supplies a constant current to the transistors Q5 and Q6.

In the example of FIG. 2, although the unit cells 4a-N are taken as examples, the configuration of the unit cells 4a-1 to 4a-(N-1) is also the same as that of the unit cells 4a-N.

As shown in FIG. 2, each of the unit cells 4a-1 to 4a-N outputs four output signals RF++, RF−−, RF−+, and RF+− to transmission lines CPW20pp, CPW20nn, CPW20np, and CPW20pn as they are, without synthesizing the output signals.

A multiplexer 5p multiplexes the output signal RF++ of the transmission line CPW20pp and the output signal RF−− of the transmission line CPW20nn with equal amplitude and equal phase. A multiplexer 5n multiplexes an output signal RF−+ of the transmission line CPW20np and an output signal RF+− of the transmission line CPW20pn with equal amplitude and equal phase.

With the aforementioned configuration, in this example, since the parasitic capacitance of the transistor added per unit length of the transmission lines CPW20pp, CPW20nn, CPW20np, and CPW20pn can be reduced to one transistor, the cut-off frequency of the pseudo transmission line can be improved, and a wide band distributed double balanced mixer can be realized.

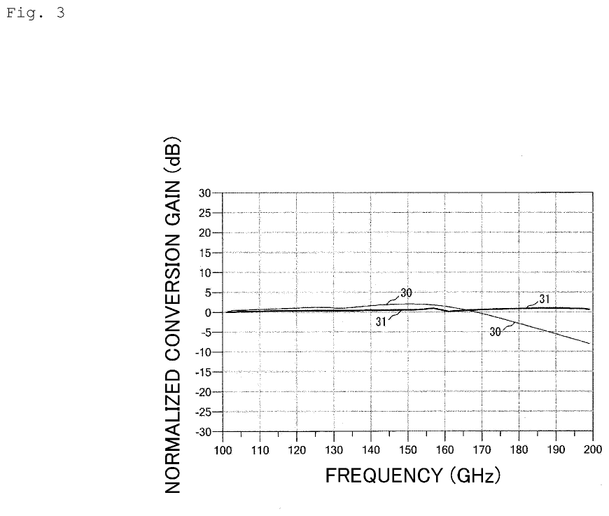

FIG. 3 is a diagram showing simulation results of the conversion gain (the ratio of the output RF signal to the input IF signal) of the distributed double balanced mixer of the related art and the present embodiment. The frequency of the IF signal is 1 GHZ to 99 GHz, and the frequency of the LO signal is 100 GHz. 30 of FIG. 3 shows the conversion gain of the distributed double balanced mixer of the related art, and 31 indicates the conversion gain of the distributed double balanced mixer of this example. The −3 dB band of the distributed double balanced mixer of the related art is 180 GHz. On the other hand, in this example, the band can be extended to 200 GHz or more as compared with the related art.

### Second Example

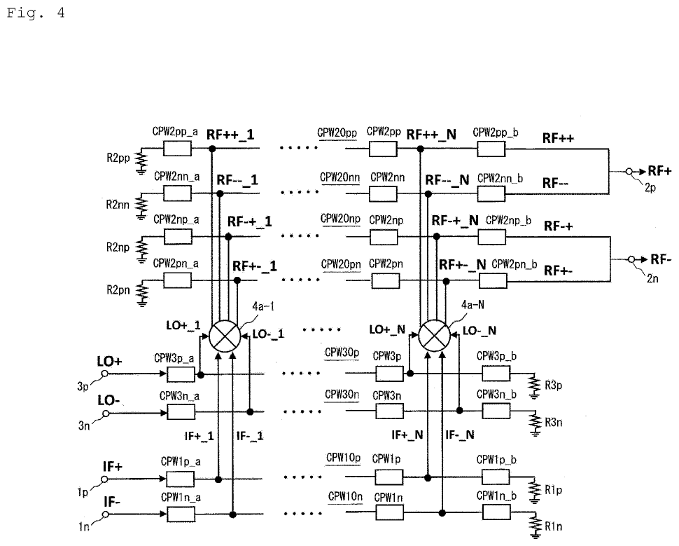

Next, a description will be given of a second example of the present invention. FIG. 4 is a circuit diagram showing the configuration of a distributed double balanced mixer according to a second example of the present invention. Differences from the first example are that, in this example, the terminals of the transmission lines CPW20p and CPW20nn are connected to the RF signal output terminal 2p without using the multiplexers 5p and 5n, and the terminals of the transmission lines CPW20np and CPW20pn are connected to the RF signal output terminal 2n.

In this way, the output signal RF++ of the transmission line CPW20pp and the output signal RF−− of the transmission line CPW20nn are multiplexed, and the output signal RF−+ of the transmission line CPW20np and the output signal RF+− of the transmission line CPW20pn are multiplexed, without using multiplexers 5p and 5n.

In this example, in addition to the same effects as those of the first example, it is possible to realize the miniaturization of the circuit and the facilitation of the layout of the circuit. When the impedance of the external element to which the output of the mixer of this example is connected is 500 which is the same as that of the general high frequency element, by setting the characteristic impedance of the transmission lines CPW20pp, CPW20nn, CPW20np, and CPW20pn to 1002, low reflection and low loss are enabled. The characteristic impedance 1000 is a critical point in the reflection loss, and the reflection loss becomes large even if it is larger or smaller than that.

### Third Example

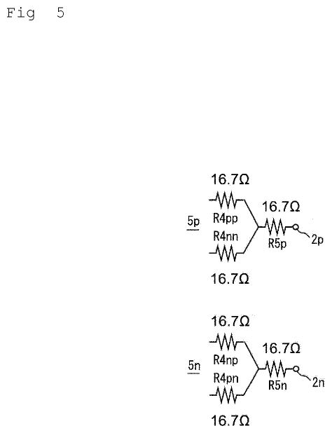

Next, a third example of the present invention will be described. This example describes a specific example of the multiplexers 5p and 5n of the first example. The multiplexer 5p of this example is a passive multiplexer as shown in FIG. 5, and is made up of a resistor R4pp of 16.7Ω having one end connected to the terminal of the transmission line CPW20pp, a resistor R4nn of 16.7Ω having one end connected to the terminal of the transmission line CPW20nn, and a resistor R5p of 16.7Ω having one end connected to the other ends of the resistors R4pp and R4nn and the other end connected to the RF signal output terminal 2p.

Similarly, the multiplexer 5n is made up of a resistor R4np of 16.7Ω having one end connected to the terminal of the transmission line CPW20np, a resistor R4pn of 16.7Ω having one end connected to the terminal of the transmission line CPW20pn, and a resistor R5n of 16.7Ω having one end connected to the other ends of the resistors R4np and R4pn, and the other end connected to the RF signal output terminal 2n.

In this example, it is possible to realize the miniaturization of the circuit and the low reflection of the output, using the passive multiplexer, in addition to the same effects as those of the first example.

### Fourth Example

Next, a fourth example of the present invention will be described.

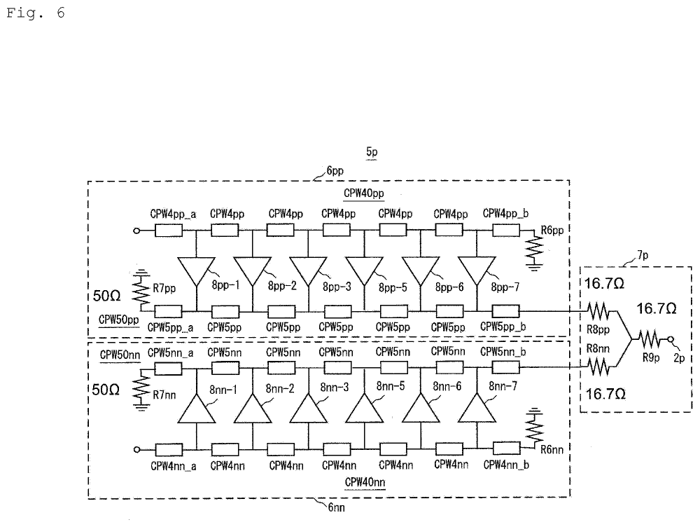

This example describes another specific example of the multiplexers 5p and 5n of the first example. The multiplexer 5p of this example is made up of distributed amplifiers 6pp and 6nn and a passive multiplexer 7p as shown in FIG. 6.

The distributed amplifier 6pp includes an input transmission line CPW40pp (ninth transmission line) whose input end is connected to the terminal of the transmission line CPW20pp, an output transmission line CPW50pp (tenth transmission line), and input terminal resistor R6pp which connects the terminal of the transmission line CPW40pp and the ground, an output terminal resistor R7pp which connects the input end of the transmission line CPW50pp and the ground, and a plurality of unit amplifiers 8pp-1 to 8pp-7 which are disposed along the transmission lines CPW40pp and CPW50pp, and have input terminals connected to the transmission lines CPW40pp and output terminals connected to the transmission lines CPW50pp.

The distributed amplifier 6nn includes an input transmission line CPW40nn (eleventh transmission line) having an input end is connected to the terminal of the transmission line CPW20nn, an output transmission line CPW50nn (twelfth transmission line), and input terminal resistor R6nn which connects the terminal of the transmission line CPW40nn and the ground, an output terminal resistor R7nn which connects the input end of the transmission line CPW50nn and the ground, and a plurality of unit amplifiers 8nn-1 to 8nn-7 which are disposed along the transmission lines CPW40nn and CPW50nn, and have input terminals connected to the transmission lines CPW40nn and output terminals are connected to the transmission lines CPW50nn.

The passive multiplexer 7p includes a resistor R8pp of 16.7Ω having one end connected to the terminal of the transmission line CPW50pp, a resistor R8nn of 16.7Ω having one end connected to the terminal of the transmission line CPW50nn, and a resistor R9p of 16.7Ω having one end connected to the other ends of the resistors R8pp and R8nn, and the other end connected to the RF signal output terminal 2p.

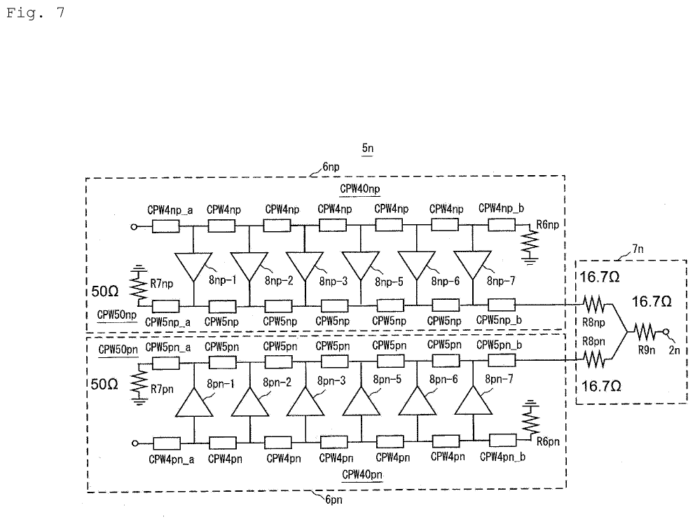

As shown in FIG. 7, the multiplexer 5n of this example is made up of distributed amplifiers 6np and 6pn and a passive multiplexer 7n.

The distributed amplifier 6np includes an input transmission line CPW40np (thirteenth transmission line) having input end connected to the terminal of the transmission line CPW20np, an output transmission line CPW50np (fourteenth transmission line), and input terminal resistor R6np which connects the terminal of the transmission line CPW40np and the ground, an output terminal resistor R7np which connects the input end of the transmission line CPW50np and the ground, and a plurality of unit amplifiers 8np-1 to 8np-7 which are disposed along the transmission lines CPW40np and CPW50np, and have input ends connected to the transmission lines CPW40np and output terminals connected to the transmission lines CPW50np.

The distributed amplifier 6pn includes an input transmission line CPW40pn (fifteenth transmission line) having an input end connected to the terminal of the transmission line CPW20pn, an output transmission line CPW50pn (sixteenth transmission line), and input terminal resistor R6pn which connects the terminal of the transmission line CPW40pn and the ground, an output terminal resistor R7pn which connects the input end of the transmission line CPW50pn and the ground, and a plurality of unit amplifiers 8pn-1 to 8pn-7 which are disposed along the transmission lines CPW40pn and CPW50pn, and have input terminals connected to the transmission line CPW40pn and output terminals connected to the transmission line CPW50pn.

The passive multiplexer 7n includes a resistor R8np of 16.7Ω having one end connected to the terminal of the transmission line CPW50np, a resistor R8pn of 16.7Ω having one end connected to the terminal of the transmission line CPW50pn, and a resistor Ron of 16.7Ω having one end connected to the other ends of the resistors R8np and R8pn, and the other end connected to the RF signal output terminal 2n.

The transmission line CPW40pp of the distributed amplifier 6pp has a configuration in which a plurality of transmission lines CPW4pp_a, CPW4pp, and CPW4pp_b are connected in series. The transmission line CPW4pp between the unit amplifiers and the transmission line CPW4pp_a on the input side have different characteristic impedances. The reason is that, in the case of the transmission line CPW4pp_a, it is necessary to absorb the influence of the parasitic capacitance of the circuit of the preceding stage by the transmission line CPW4pp_a. Similarly, the transmission lines CPW4pp and CPW4pp_b have different characteristic impedances. The reason is that, in the case of the transmission line CPW4pp_b, it is necessary to absorb the influence of the parasitic capacitance of the passive multiplexer 7p of the subsequent stage by the transmission line CPW4pp_b.

The transmission line CPW40pn of the distributed amplifier 6pn has a configured in which a plurality of transmission lines CPW4pn_a, CPW4pn, CPW4pn_b are connected in series. The transmission line CPW40np of the distributed amplifier 6np has a configuration in which a plurality of transmission lines CPW4np_a, CPW4np, and CPW4np_b are connected in series. The transmission line CPW40nn of the distributed amplifier 6nn has a configuration in which a plurality of transmission lines CPW4nn_a, CPW4nn, and CPW4nn_b are connected in series.

The transmission line CPW50pp of the distributed amplifier 6pp has a configuration in which a plurality of transmission lines CPW5pp_a, CPW5pp, and CPW5pp_b are connected in series. The transmission line CPW5pp between the unit amplifiers and the transmission line CPW5pp_a on the input side have different characteristic impedances. The reason is that, in the case of the transmission line CPW5pp_a, it is necessary to absorb the influence of the parasitic capacitance of the output terminal resistor R7pp by the transmission line CPW5pp_a. Similarly, the transmission lines CPW5pp and CPW5pp_b have different characteristic impedances. The reason is that, in the case of the transmission line CPW5pp_b, it is necessary to absorb the influence of the parasitic capacitance of the passive multiplexer 7p of the subsequent stage by the transmission line CPW5pp_b.

The transmission line CPW50pn of the distributed amplifier 6pn has a configuration in which a plurality of transmission lines CPW5pn_a, CPW5pn, and CPW5pn_b are connected in series. The transmission line CPW50np of the distributed amplifier 6np has a configuration in which a plurality of transmission lines CPW5np_a, CPW5np, and CPW5np_b are connected in series. The transmission line CPW50nn of the distributed amplifier 6nn has a configuration in which a plurality of transmission lines CPW5nn_a, CPW5nn, and CPW5nn_b are connected in series.

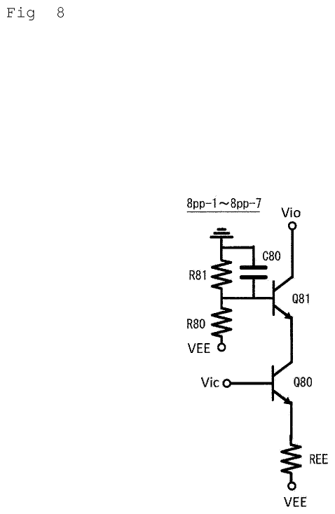

As shown in FIG. 8, each of the unit amplifiers 8pp-1 to 8pp-7 of the distributed amplifier 6pp includes a transistor Q80 having a base terminal connected to the transmission line CPW40pp, a transistor Q81 having a collector terminal connected to the transmission line CPW50pp and an emitter terminal connected to the collector terminal of the transistor Q80, an emitter resistor REE having one end connected to the emitter terminal of the transistor Q80 and the other end connected to a power supply voltage VEE, a resistor R80 having one end connected to the power supply voltage VEE and the other end connected to the base terminal of the transistor Q81, a resistor R81 having one end connected to the base terminal of the transistor Q81 and other end connected to the ground, and a capacitor C80 having one end connected to the base terminal of the transistor Q81 and the other end connected to the ground.

In the example of FIG. 7, although the unit amplifiers 8pp-1 to 8pp-7 are taken as examples, in the case of the unit amplifiers 8pn-1 to 8pn-7 of the distributed amplifier 6pn, the base terminal of the transistor Q80 may be connected to the transmission line CPW40pn, and the collector terminal of the transistor Q81 may be connected to the transmission line CPW50pn. In the case of the unit amplifiers 8np-1 to 8np-7 of the distributed amplifier 6np, the base terminal of the transistor Q80 may be connected to the transmission line CPW40np, and the collector terminal of the transistor Q81 may be connected to the transmission line CPW50np. In the case of the unit amplifiers 8nn-1 to 8nn-7 of the distributed amplifier 6nn, the base terminal of the transistor Q80 may be connected to the transmission line CPW40nn, and the collector terminal of the transistor 081 may be connected to the transmission line PW50nn.

In the examples of FIGS. 6 and 7, although the number of each of the unit amplifiers 8pp-1 to 8pp-7, 8pn-1 to 8pn-7, 8np-1 to 8np-7, and 8nn-1 to 8nn-7 is set to 7, it is needless to say that the number is not limited to 7.

In this way, in this example, the conversion gain can be improved and the output can be reduced, using the distributed multiplexer including the distributed amplifier and the passive multiplexer for the multiplexers 5p and 5n, in addition to the same effect as in the first example.

Further, in this example, the conversion gain can be further improved, by setting the characteristic impedances of the transmission lines CPW20pp, CPW20nn, CPW20np, and CPW20pn and the output terminal resistors R2pp, R2nn, R2np, and R2pn described in the first example to be higher than 50Ω, and furthermore, by setting the characteristic impedances of the transmission lines CPW40pp, CPW40nn, CPW40np, and CPW40pn of the distributed multiplexer and the input terminal resistors R6pp, R6nn, R6np, and R6pn to be higher than 50Ω.

### Fifth Example

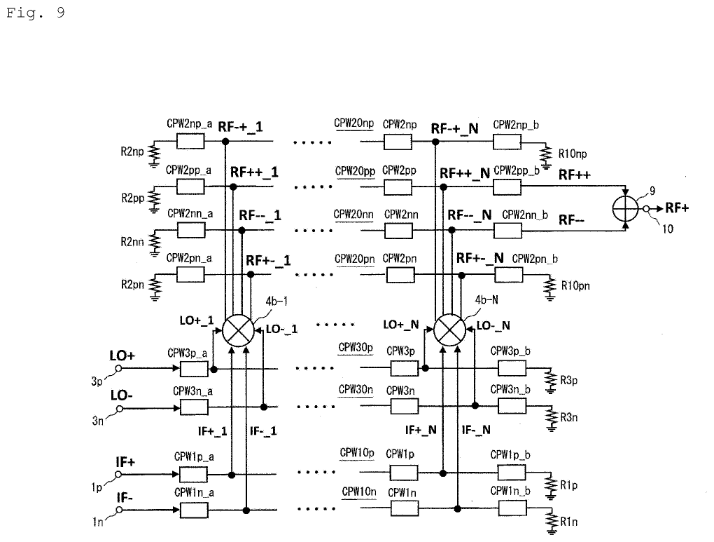

Although the differential input differential output type distributed double balanced mixer has been described in the first to fourth examples, the configuration shown in FIG. 9 can be adopted when the output of the mixer may be a single phase output. The distributed double balanced mixer of this example includes transmission lines for IF signal input CPW10p and CPW10n; transmission lines for RF signal output CPW20pp, CPW20nn, CPW20np, and CPW20pn; transmission lines for LO signal input CPW30p and CPW30n; input terminal resistors R1p and R1n; output terminal resistors R2pp, R2nn, R2np, and R2pn; terminal resistors R3p and R3n; a plurality of unit cells 4b-1 to 4b-N(N is an integer of 2 or more) which are disposed along the transmission lines CPW10p, CPW10n, CPW20pp, CPW20nn, CPW20np, CPW20pn, CPW30p, and CPW30n, and in which the IF input terminal is connected to the transmission lines CPW10p and CPW10n, the LO input terminal is connected to the transmission lines CPW30p and CPW30n, and the RF output terminal is connected to the transmission lines CPW20pp, CPW20nn, CPW20np and CPW20pn; terminal resistors R10np and R10pn which connect the terminals of the transmission lines CPW20np and CPW20pn and the ground; and a multiplexer 9 which multiplexes the output signal RF++ of the transmission line CPW20pp and the output signal RF−− of the transmission line CPW20nn with equal amplitude and equal phase and outputting them to the RF signal output terminal 10.

In the first to fourth examples, transmission lines CPW20pp, CPW20nn, CPW20np, and CPW20pn are disposed in this order. On the other hand, in this example, the transmission lines CPW20np, CPW20pp, CPW20nn, and CPW20pn are disposed in this order. That is, the transmission lines CPW20pp and CPW20nn are disposed adjacent to each other, the transmission line CPW20np is disposed on the opposite side of the transmission line CPW20nn with the transmission line CPW20pp interposed therebetween, and the transmission line CPW20pn is disposed on the opposite side of the transmission line CPW20pp with the transmission line CPW20nn interposed therebetween.

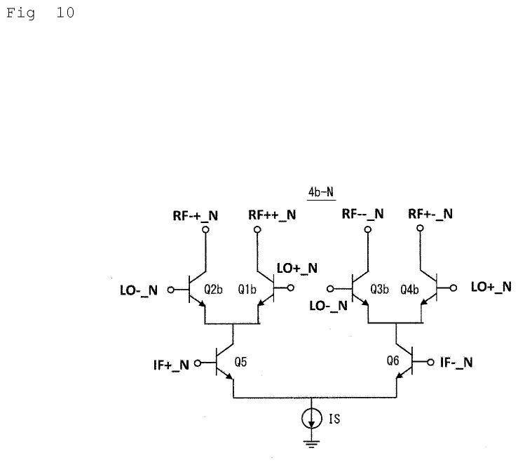

As shown in FIG. 10, a unit cell 4b-N includes an NPN bipolar transistor Q1b having a base terminal connected to the transmission line CPW30p and a collector terminal connected to the transmission line CPW20pp; an NPN bipolar transistor Q2b having a base terminal connected to the transmission line CPW30n and a collector terminal connected to the transmission line CPW20np; an NPN bipolar transistor Q3b having a base terminal connected to the transmission line CPW30n and a collector terminal connected to the transmission line CPW20nn; an NPN bipolar transistor Q4b having a base terminal connected to the transmission line CPW30p and a collector terminal connected to the transmission line CPW20pn; an NPN bipolar transistor Q5 having a base terminal connected to the transmission line CPW10p and a collector terminal connected to the emitter terminals of the transistors Q1b and Q2b; an NPN bipolar transistor Q6 having a base terminal connected to transmission line CPW10n and a collector terminal connected to the emitter terminals of transistors Q3b and Q4b; and a constant current source IS which has one end connected to the emitter terminals of the transistors Q5 and Q6 and the other end connected to ground, and supplies a constant current to the transistors Q5 and Q6.

In the example of FIG. 10, although the unit cell 4b-N is taken as an example, the configuration of the unit cells 4b-1 to 4b-(N-1) is also the same as that of the unit cell 4b-N.

In this example, unnecessary intersection on the circuit layout is not required, and a wide band and a simplification of the circuit layout can be realized.

### INDUSTRIAL APPLICABILITY

The present invention can be applied to a mixer circuit that converts the frequency of a signal.

### REFERENCE SIGNS LIST

1p, 1n IF signal input ends
2p, 2n, 10 RF signal output terminal
3p, 3n LO signal input terminal
4a-1 to 4 a-N, 4b-1 to 4b-N Unit cell
5p, 5n, 9 Multiplexer
6pp, 6pn Distributed amplifier
7p Passive multiplexer
8pp-1 to 8pp-7, 8nn-1 to 8nn-7, 8np-1 to 8np-7, 8pn-1 to 8pn-7 Unit amplifier
CPW1p, CPW1p_a, CPW1p_b, CPW1n, CPW1n_a, CPW1n_b, CPW2pp, CPW2pp_a, CPW2pp_b, CPW2pn, CPW2pn_a, CPW2pn_b, CPW2np, CPW2np_a, CPW2np_b, CPW2nn, CPW2nn_a, CPW2nn_b, CPW3p, CPW3p_a, CPW3p_b, CPW3n, CPW3n_a, CPW3n_b, CPW4pp, CPW4pp_a, CPW4pp_b, CPW4pn, CPW4pn_a, CPW4pn_b, CPW4np, CPW4np_a, CPW4np_b, CPW4nn, CPW4nn_a, CPW4nn_b, CPW5pp, CPW5pp_a, CPW5pp_b, CPW5pn, CPW5pn_a, CPW5pn_b, CPW5np, CPW5np_a, CPW5np_b, CPW5nn, CPW5nn_a, CPW5nn_b, CPW10p, CPW10n, CPW20pp, CPW20nn, CPW20np, CPW20pn, CPW30p, CPW30n, CPW40pp, CPW40nn, CPW40np, CPW40pn, CPW50pp, CPW50nn, CPW50np, CPW50pn Transmission line
Q1, Q1b, Q2, Q2b, Q3, Q3b, Q4, Q4b, Q5, Q6, Q80, Q81 Transistor
R1p, R1n, R2pp, R2nn, R2np, R2pn, R3p, R3n, R4pp, R4pn, R4np, R4nn, R5p, R5n, R6pp, R6nn, R6np, R6pn, R7pp, R7pn, R7np, R7nn, R8pp, R8pn, R8np, R8nn, R9p, R9n, R10np, R10pn, R80, R81 Resistor
C80 Capacitor
IS Constant current source

1-8. (canceled)

9. A distributed double balanced mixer comprising:
a first transmission line configured to receive an IF signal of a positive phase side at an input end of the first transmission line;
a second transmission line configured to receive the IF signal of a negative phase side at an input end of the second transmission line;
a third transmission line configured to receive an LO signal of the positive phase side at an input end of the third transmission line;
a fourth transmission line configured to receive an LO signal of the negative phase side at an input end of the fourth transmission line;
a fifth transmission line configured to output a signal obtained by multiplexing the LO signal of the positive phase side and the IF signal of the positive phase side;
a sixth transmission line configured to output a signal obtained by multiplexing the LO signal of the negative phase side and the IF signal of the negative phase side;
a seventh transmission line configured to output a signal obtained by multiplexing the LO signal of the negative phase side and the IF signal of the positive phase side;
an eighth transmission line configured to output a signal obtained by multiplexing the LO signal of the positive phase side and the IF signal of the negative phase side;
first and second terminal resistors connected to the first and second transmission lines;
third and fourth terminal resistors connected to the third and fourth transmission lines;
fifth to eighth terminal resistors connected to input ends of the fifth to eighth transmission lines, respectively; and
a plurality of unit cells which are disposed along the first to eighth transmission lines, and in which an IF input terminal is connected to the first and second transmission lines, an LO input terminal is connected to the third and fourth transmission lines, and RF output terminals are connected to the fifth to eighth transmission lines,
wherein each of the plurality of unit cells includes:
a first transistor having a base terminal connected to the third transmission line and a collector terminal connected to the fifth transmission line,
a second transistor having a base terminal connected to the fourth transmission line and a collector terminal connected to the seventh transmission line,
a third transistor having a base terminal connected to the fourth transmission line and a collector terminal connected to the sixth transmission line,
a fourth transistor having a base terminal connected to the third transmission line and a collector terminal connected to the eighth transmission line,
a fifth transistor having a base terminal connected to the first transmission line and a collector terminal connected to emitter terminals of the first and second transistors,
a sixth transistor having a base terminal connected to the second transmission line and a collector terminal connected to emitter terminals of the third and fourth transistors, and
a constant current source having a first end connected to emitter terminals of the fifth and sixth transistors and a second end connected to ground.

10. The distributed double balanced mixer according to claim 9, further comprising:
a first multiplexer configured to multiplex an output signal of the fifth transmission line and an output signal of the sixth transmission line to output an RF signal of the positive phase side; and
a second multiplexer configured to multiplex an output signal of the seventh transmission line and an output signal of the eighth transmission line to output an RF signal of the negative phase side.

11. The distributed double balanced mixer according to claim 10, wherein:
the RF signal of the positive phase side is output from a connection point between the fifth transmission line and the sixth transmission line; and
the RF signal of the negative phase side is output from a connection point between the seventh transmission line and the eighth transmission line.

12. The distributed double balanced mixer according to claim 11,
wherein the fifth to eighth transmission lines have a characteristic impedance of 100 Ω.

13. The distributed double balanced mixer according to claim 10, wherein the first multiplexer is configured by a first passive multiplexer which includes:
a first resistor of 16.7Ω having a first end connected to the fifth transmission line;
a second resistor of 16.7Ω having a first end connected to the sixth transmission line; and
a third resistor of 16.7Ω which a first one end connected to second ends of the first and second resistors, and is configured to output the RF signal of the positive phase side from a second end of the third resistor.

14. The distributed double balanced mixer according to claim 13, wherein the second multiplexer is configured by a first passive multiplexer which includes:
a fourth resistor of 16.7Ω having a first end connected to the seventh transmission line;
a fifth resistor of 16.7Ω having a first end connected to the eighth transmission line; and
a sixth resistor of 16.7Ω which has a first end connected to second ends of the fourth and fifth resistors, and is configured to output an RF signal on the negative phase side from a second end of the sixth resistor.

15. The distributed double balanced mixer according to claim 10, wherein the first multiplexer includes:
a first distributed amplifier which receives an output signal of the fifth transmission line as an input;
a second distributed amplifier which receives an output signal of the sixth transmission line as an input; and
a first passive multiplexer configured to multiplex an output signal of the first distributed amplifier and an output signal of the second distributed amplifier.

16. The distributed double balanced mixer according to claim 15, wherein the second multiplexer includes:
a third distributed amplifier which receives an output signal of the seventh transmission line as an input;
a fourth distributed amplifier which receives an output signal of the eighth transmission line as an input; and
a second passive multiplexer configured to multiplex the output signal of the third distributed amplifier and the output signal of the fourth distributed amplifier.

17. The distributed double balanced mixer according to claim 16, wherein the first distributed amplifier includes:
a ninth transmission line configured to receive an output signal of the fifth transmission line at an input end of the ninth transmission line;
a tenth transmission line configured to output a signal;
a ninth terminal resistor having a first end connected to the ninth transmission line;
a tenth terminal resistor having a first end connected to an input end of the tenth transmission line; and
a plurality of first unit amplifiers which are disposed along the ninth transmission line and the tenth transmission line, and in which an input terminal is connected to the ninth transmission line, and an output terminal is connected to the tenth transmission line.

18. The distributed double balanced mixer according to claim 17, wherein the second distributed amplifier includes:
an eleventh transmission line configured such that an output signal of the sixth transmission line is input to an input end of the eleventh transmission line;
a twelfth transmission line configured to output a signal;
an eleventh terminal resistor having a first end connected to the eleventh transmission line;
a twelfth terminal resistor having one end connected to an input end of the twelfth transmission line; and
a plurality of second unit amplifiers which are disposed along the eleventh transmission line and the twelfth transmission line, and in which an input terminal is connected to the eleventh transmission line, and an output terminal is connected to the twelfth transmission line.

19. The distributed double balanced mixer according to claim 18, wherein the third distributed amplifier includes:
a thirteenth transmission line configured such that an output signal of the seventh transmission line is input to an input end of the thirteenth transmission line;
a fourteenth transmission line configured to output a signal;
a thirteenth terminal resistor having a first end connected to the thirteenth transmission line;
a fourteenth terminal resistor having a first end connected to an input end of the fourteenth transmission line; and
a plurality of third unit amplifiers which are disposed along the thirteenth transmission line and the fourteenth transmission line, and in which an input terminal is connected to the thirteenth transmission line, and an output terminal is connected to the fourteenth transmission line.

20. The distributed double balanced mixer according to claim 19, wherein the fourth distributed amplifier includes
a fifteenth transmission line configured such that an output signal of the eighth transmission line is input to an input end of the fifteenth transmission line;
a sixteenth transmission line configured to output a signal;
a fifteenth terminal resistor having a first end connected to the fifteenth transmission line;
a sixteenth terminal resistor having a first end connected to an input end of the sixteenth transmission line; and
a plurality of fourth unit amplifiers which are disposed along the fifteenth transmission line and the sixteenth transmission line, and in which an input terminal is connected to the fifteenth transmission line, and an output terminal is connected to the sixteenth transmission line.

21. The distributed double balanced mixer according to claim 20, wherein the characteristic impedances of the fifth to eighth transmission lines and the fifth to eighth terminal resistors are higher than 50Ω, and the characteristic impedances of the ninth, eleventh, thirteenth, and fifteenth transmission lines, and the ninth, eleventh, thirteenth and fifteenth terminal resistors are higher than 50 Ω.

22. The distributed double balanced mixer according to claim 9, further comprising:
a multiplexer configured to multiplex an output signal of the fifth transmission line and an output signal of the sixth transmission line to output an RF signal, wherein the seventh transmission line, the fifth transmission line, the sixth transmission line, and the eighth transmission line are disposed on a plane in that order.

23. A distributed double balanced mixer comprising:
a first transmission line configured to receive an IF signal of a positive phase side;
a second transmission line configured to receive the IF signal of a negative phase side;
a third transmission line configured to receive an LO signal of the positive phase side;
a fourth transmission line configured to receive an LO signal of the negative phase side;
a fifth transmission line configured to output a signal obtained by multiplexing the LO signal of the positive phase side and the IF signal of the positive phase side;
a sixth transmission line configured to output a signal obtained by multiplexing the LO signal of the negative phase side and the IF signal of the negative phase side;
a seventh transmission line configured to output a signal obtained by multiplexing the LO signal of the negative phase side and the IF signal of the positive phase side;
an eighth transmission line configured to output a signal obtained by multiplexing the LO signal of the positive phase side and the IF signal of the negative phase side; and
a plurality of unit cells which are disposed along the first to eighth transmission lines, wherein each of the plurality of unit cells includes:
a first transistor having a base terminal connected to the third transmission line and a collector terminal connected to the fifth transmission line,
a second transistor having a base terminal connected to the fourth transmission line and a collector terminal connected to the seventh transmission line,
a third transistor having a base terminal connected to the fourth transmission line and a collector terminal connected to the sixth transmission line,
a fourth transistor having a base terminal connected to the third transmission line and a collector terminal connected to the eighth transmission line,
a fifth transistor having a base terminal connected to the first transmission line and a collector terminal connected to emitter terminals of the first and second transistors,
a sixth transistor having a base terminal connected to the second transmission line and a collector terminal connected to emitter terminals of the third and fourth transistors, and
a constant current source having a first end connected to emitter terminals of the fifth and sixth transistors and a second end connected to ground.

24. The distributed double balanced mixer according to claim 23, further comprising:
first and second terminal resistors connected to the first and second transmission lines;
third and fourth terminal resistors connected to the third and fourth transmission lines; and
fifth to eighth terminal resistors connected to input ends of the fifth to eighth transmission lines, respectively.
